(19) United States
(12) Patent Application Publication
(10) Pub. No.: US 2024/0243708 A1
(43) Pub. Date: Jul. 18, 2024

(54) DISTRIBUTED POWER MANAGEMENT CIRCUIT

(71) Applicant: Qorvo US, Inc., Greensboro, NC (US)

(72) Inventor: Nadim Khlat, Cugnaux (FR)

(21) Appl. No.: 18/394,038

(22) Filed: Dec. 22, 2023

Related U.S. Application Data
(60) Provisional application No. 63/480,201, filed on Jan. 17, 2023.

(51) Int. Cl. H03F 3/24; H03F 1/02; H04B 1/04; H04B 1/40

(52) U.S. Cl. CPC H03F 3/245; H03F 1/0227; H04B 1/0483; H04B 1/40; H03F 2200/451; H04B 2001/0408; H04B 2001/0416

(57) ABSTRACT

A distributed power management circuit is provided. The distributed power management circuit includes a main power management integrated circuit (PMIC) and multiple distributed PMICs separated from the main PMIC. The main PMIC is configured to generate a number of voltages for a set of main power amplifier circuits located closer to the main PMIC and the distributed PMICs are configured to generate multiple distributed voltages for a set of distributed power amplifier circuits located closer to the distributed PMICs. In this regard, it is possible to reduce trace inductance between the main PMIC and the set of main power amplifier circuits and between the distributed PMICs and the distributed power amplifier circuits. As a result, it is possible to reduce unwanted distortion in both the main power amplifier circuits and the distributed power amplifier circuits.

### RELATED APPLICATIONS

This application claims the benefit of U.S. provisional patent application Ser. No. 63/480,201, filed on Jan. 17, 2023, the disclosure of which is hereby incorporated herein by reference in its entirety.

### FIELD OF THE DISCLOSURE

The technology of the disclosure relates generally to a power management circuit.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by wireless communication technologies, such as fifth-generation new-radio (5G-NR) technology configured to communicate a millimeter wave (mmWave) radio frequency (RF) signal(s) in an mmWave spectrum located above 12 GHz frequency. To achieve higher data rates, a mobile communication device may employ a power amplifier(s) to increase output power of the mmWave RF signal(s) (e.g., maintaining sufficient energy per bit). However, the increased output power of the mmWave RF signal(s) can lead to increased power consumption and thermal dissipation in the mobile communication device, thus compromising overall performance and user experience.

Envelope tracking (ET) is a power management technology designed to improve efficiency levels of power amplifiers to help reduce power consumption and thermal dissipation in mobile communication devices. In an ET system, a power amplifier(s) amplifies an RF signal(s) based on a time-variant ET voltage(s) generated in accordance with time-variant amplitudes of the RF signal(s). More specifically, the time-variant ET voltage(s) corresponds to a time-variant voltage envelope(s) that tracks (e.g., rises and falls) a time-variant power envelope(s) of the RF signal(s). Understandably, the better the time-variant voltage envelope(s) tracks the time-variant power envelope(s), the higher linearity the power amplifier(s) can achieve.

However, the time-variant ET voltage(s) can be highly susceptible to distortions caused by trace inductance, particularly when the time-variant ET voltage(s) is so generated to track the time-variant power envelope(s) of a high modulation bandwidth (e.g., >200 MHZ) RF signal(s). As a result, the time-variant voltage envelope(s) may become misaligned with the time-variant power envelope(s) of the RF signal(s), thus causing unwanted distortions (e.g., amplitude clipping) in the RF signal(s). In this regard, it may be necessary to ensure that the ET power amplifier(s) can consistently operate at a desired linearity for any given instantaneous power requirement of the RF signal(s).

### SUMMARY

Embodiments of the disclosure relate to a distributed power management circuit. The distributed power management circuit includes a main power management integrated circuit (PMIC) and multiple distributed PMICs separated from the main PMIC. The main PMIC is configured to generate a number of voltages for a set of main power amplifier circuits located closer to the main PMIC, and the distributed PMICs are configured to generate multiple distributed voltages for a set of distributed power amplifier circuits located closer to the distributed PMICs. In this regard, it is possible to reduce trace inductance between the main PMIC and the set of main power amplifier circuits and between the distributed PMICs and the distributed power amplifier circuits. As a result, it is possible to reduce unwanted distortion in both the main power amplifier circuits and the distributed power amplifier circuits.

In one aspect, a distributed power management circuit is provided. The distributed power management circuit includes multiple distributed PMICs. Each of the multiple distributed PMICs is configured to generate a respective one of multiple distributed voltages based on a respective one of multiple distributed target voltages. The distributed power management circuit also includes a main PMIC. The main PMIC includes multiple voltage circuits. Each of the multiple voltage circuits is configured to generate a respective one of multiple voltages and/or a respective one of multiple low-frequency currents based on a respective one of multiple target voltages. The main PMIC also includes a control circuit. The control circuit is configured to determine that at least two selected distributed PMICs among the multiple distributed PMICs are needed to concurrently generate at least two distributed voltages among the multiple distributed voltages. The control circuit is also configured to cause at least two selected voltage circuits among the multiple voltage circuits to each generate exclusively the respective one of the multiple low-frequency currents. The control circuit is also configured to couple each of the at least two selected voltage circuits to a respective one of the at least two selected distributed PMICs to thereby provide the respective one of the multiple low-frequency currents to the respective one of the at least two selected distributed PMICs.

In another aspect, a wireless device is provided. The wireless device includes a distributed power management circuit. The distributed power management circuit includes multiple distributed PMICs. Each of the multiple distributed PMICs is configured to generate a respective one of multiple distributed voltages based on a respective one of multiple distributed target voltages. The distributed power management circuit also includes a main PMIC. The main PMIC includes multiple voltage circuits. Each of the multiple voltage circuits is configured to generate a respective one of multiple voltages and/or a respective one of multiple low-frequency currents based on a respective one of multiple target voltages. The main PMIC also includes a control circuit. The control circuit is configured to determine that at least two selected distributed PMICs among the multiple distributed PMICs are needed to concurrently generate at least two distributed voltages among the multiple distributed voltages. The control circuit is also configured to cause at least two selected voltage circuits among the multiple voltage circuits to each generate exclusively the respective one of the multiple low-frequency currents. The control circuit is also configured to couple each of the at least two selected voltage circuits to a respective one of the at least two selected distributed PMICs to thereby provide the respective one of the multiple low-frequency currents to the respective one of the at least two selected distributed PMICs.

In another aspect, a method for operating a distributed power management circuit is provided. The method includes configuring multiple distributed PMICs to each generate a respective one of multiple distributed voltages based on a respective one of multiple distributed target voltages. The method also includes configuring multiple voltage circuits to each generate a respective one of multiple voltages and a respective one of multiple low-frequency currents based on a respective one of multiple target voltages. The method also includes determining that at least two selected distributed PMICs among the multiple distributed PMICs are needed to concurrently generate at least two distributed voltages among the multiple distributed voltages. The method also includes causing at least two selected voltage circuits among the multiple voltage circuits to each generate exclusively the respective one of the multiple low-frequency currents. The method also includes coupling each of the at least two selected voltage circuits to a respective one of the at least two selected distributed PMICs to thereby provide the respective one of the multiple low-frequency currents to the respective one of the at least two selected distributed PMICs.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary distributed power management circuit configured according to an embodiment of the present disclosure to include a main power management integrated circuit (PMIC) and multiple distributed PMICs;

FIG. 2 is a schematic diagram providing an exemplary illustration of a voltage circuit in the main PMIC in FIG. 1;

FIG. 3 is a schematic diagram providing an exemplary illustration of any of the distributed PMICs in the distributed power management circuit of FIG. 1;

FIG. 4 is a schematic diagram of a wireless device incorporating the distributed power management circuit of FIG. 1;

FIG. 5 is a schematic diagram of an exemplary user element that can be functionally equivalent to the wireless device of FIG. 4; and

FIG. 6 is a flowchart of an exemplary process for operating the distributed power management circuit of FIG. 1 in the wireless device of FIG. 4.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a distributed power management circuit. The distributed power management circuit includes a main power management integrated circuit (PMIC) and multiple distributed PMICs separated from the main PMIC. The main PMIC is configured to generate a number of voltages for a set of main power amplifier circuits located closer to the main PMIC, and the distributed PMICs are configured to generate multiple distributed voltages for a set of distributed power amplifier circuits located closer to the distributed PMICs. In this regard, it is possible to reduce trace inductance between the main PMIC and the set of main power amplifier circuits, and between the distributed PMICs and the distributed power amplifier circuits. As a result, it is possible to reduce unwanted distortion in both the main power amplifier circuits and the distributed power amplifier circuits.

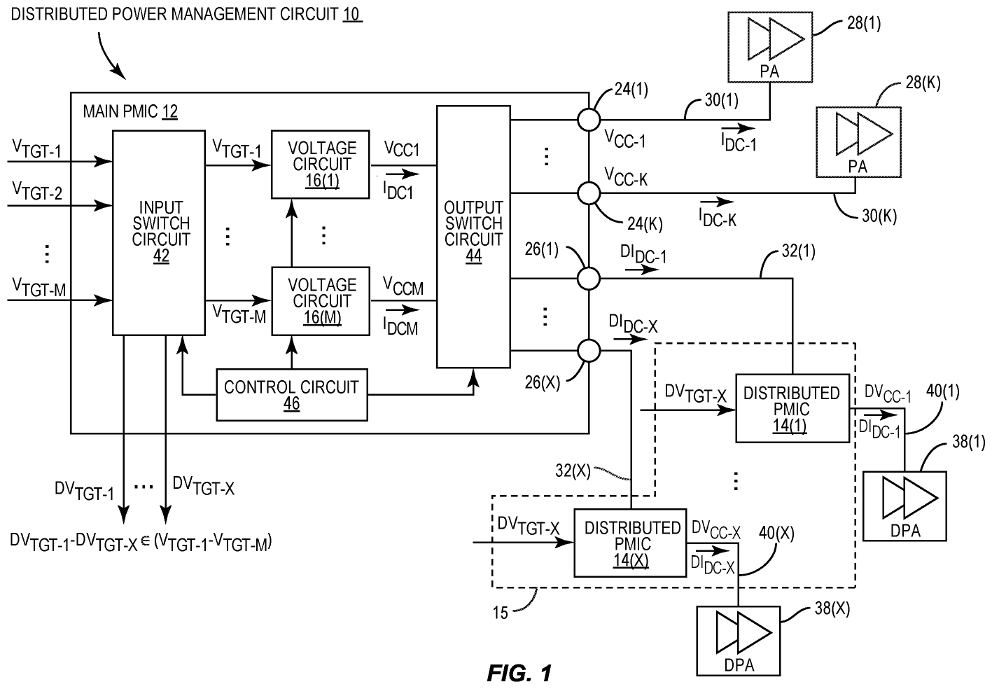

FIG. 1 is a schematic diagram of an exemplary distributed power management circuit 10 configured according to an embodiment of the present disclosure to include a main power management integrated circuit (PMIC) 12 and multiple distributed PMICs 14(1)-14(X). Notably, the main PMIC 12 is a separate circuit from each of the distributed PMICs 14(1)-14(X). However, the distributed PMICs 14(1)-14(X) can be separated from one another or integrated into a single distributed PMIC 15.

The main PMIC 12 includes a number of voltage circuits 16(1)-16(M). Each of the voltage circuits 16(1)-16(M) can be configured to generate a respective one of multiple voltages V_{CC1}-V_{CCM} and a respective one of multiple low-frequency currents I_{DC1}-I_{DCM} (e.g., direct currents) based on a respective one of multiple target voltages V_{TGT-1}-V_{TGT-M}. Depending on specific configurations, the voltage circuits 16(1)-16(M) may generate the voltages V_{CC1}-V_{CCM} as envelope tracking (ET) voltages, average power tracking (APT) voltages, or a mixture of ET and APT voltages.

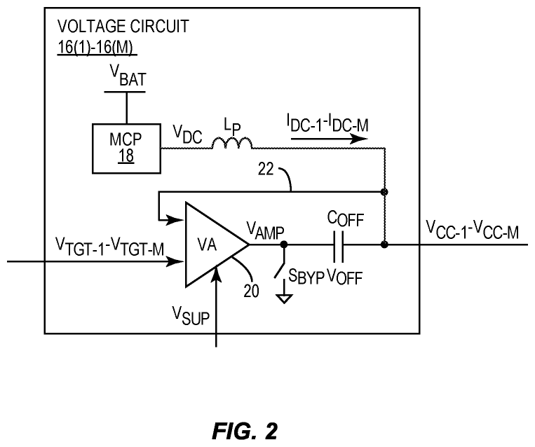

FIG. 2 is a schematic diagram providing an exemplary illustration of any of the voltage circuits 16(1)-16(M) in the main PMIC 12 in FIG. 1. Common elements between FIGS. 1 and 2 are shown therein with common element numbers and will not be re-described herein.

Herein, each of the voltage circuits 16(1)-16(M) includes a multi-level charge pump (MCP) 18 coupled in series to a power inductor L_{P}. The MCP 18, which can be a direct-current-direct-current (DC-DC) converter, is configured to generate a low-frequency voltage V_{DC} based on a battery voltage V_{BAT}. In a non-limiting example, the MCP 18 can operate in a buck mode to generate the low-frequency voltage at 0V or V_{BAT}, or in a boost mode to generate the low-frequency voltage at 2*V_{BAT}. Moreover, the MCP 18 may toggle the low-frequency voltage between 0V, V_{BAT}, and/or 2*V_{BAT} according to a specific duty cycle to thereby generate the low-frequency voltage V_{DC} at any desired voltage level. The power inductor L_{P} is configured to induce a respective one of the low-frequency currents I_{DC1}-I_{DCM} based on the low-frequency voltage V_{DC}.

Each of the voltage circuits 16(1)-16(M) includes a voltage amplifier 20 (denoted as “VA”) coupled in series to an offset capacitor C_{OFF}. The voltage amplifier 20 is configured to generate an initial ET voltage VAMP based on a respective one of the target voltages V_{TGT-1}-V_{TGT-M} and a supply voltage V_{SUP}. The offset capacitor C_{OFF} is charged by a respective one of the low-frequency currents I_{DC1}-I_{DCM} to raise the initial ET voltage VAMP by an offset voltage VOFF to thereby generate a respective one of the voltages V_{CC1}-V_{CCM}.

Each of the voltage circuits 16(1)-16(M) also includes a bypass switch S_{BYP} having one end coupled in between the voltage amplifier 20 and the offset capacitor C_{OFF}, and another end to a ground (GND). The bypass switch S_{BYP} is closed while the offset capacitor C_{OFF} is being charged toward the offset voltage VOFF and opened when the offset capacitor C_{OFF} is charged to the offset voltage VOFF. Each of the voltage circuits 16(1)-16(M) also includes a feedback loop 22 that feeds a copy of the respective one of the voltages V_{CC1}-V_{CCM} back to the voltage amplifier 20.

With reference back to FIG. 1, the distributed PMICs 14(1)-14(X) are each configured to generate a respective one of multiple distributed voltages DV_{CC-1}-DV_{CC-X} based on a respective one of multiple distributed target voltages DV_{TGT-1}-DV_{TGT-X}. According to an embodiment of the present disclosure, the distributed power management circuit 10 includes a lesser number of the distributed PMICs 14(1)-14(X) than the voltage circuits 16(1)-16(M) (X<M). Accordingly, the distributed target voltages DV_{TGT-1}-DV_{TGT-X} will be a subset of the target voltages V_{TGT-1}-V_{TGT-M} (DV_{TGT-1}-DV_{TGT-X}∈(V_{TGT-1}-V_{TGT-M})).

The main PMIC 12 can include a first set of voltage outputs 24(1)-24(K) and a second set of voltage outputs 26(1)-26(X) (K+X=M). Each of the first set of voltage outputs 24(1)-24(K) is coupled to a respective one of multiple main power amplifier circuits 28(1)-28(K) via a respective one of multiple first conductive paths 30(1)-30(K). Herein, the first set of voltage outputs 24(1)-24(K) are configured to output a subset of the voltages V_{CC1}-V_{CCM} (denoted as V_{CC-1}-V_{CC-K}) and a subset of the low-frequency currents I_{DC1}-I_{DCM} (denoted as I_{DC-1}-I_{DC-K}) to the main power amplifier circuits 28(1)-28(K) via the first conductive paths 30(1)-30(K), respectively.

Each of the second set of voltage outputs 26(1)-26(X) is coupled to a respective one of the distributed PMICs 14(1)-14(X) via a respective one of multiple second conductive paths 32(1)-32(X). Herein, none of the distributed PMICs 14(1)-14(X) can generate its own low-frequency current. Instead, the distributed PMICs 14(1)-14(X) are configured to receive a subset of the low-frequency currents I_{DC1}-I_{DCM} (denoted as DI_{DC-1}-DI_{DC-X}) via the second set of voltage outputs 26(1)-26(X), respectively.

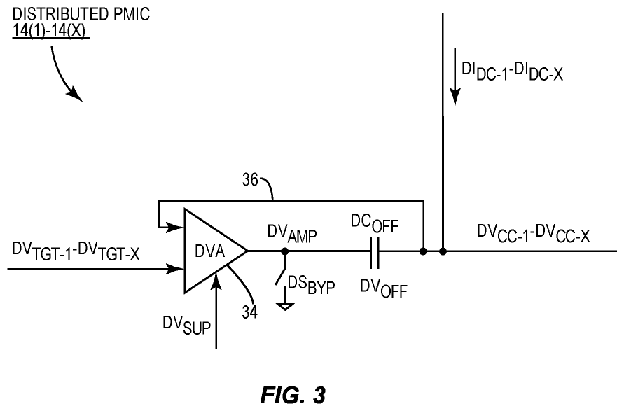

FIG. 3 is a schematic diagram providing an exemplary illustration of any of the distributed PMICs 14(1)-14(X) in the distributed power management circuit 10 of FIG. 1. Common elements between FIGS. 1 and 3 are shown therein with common element numbers and will not be re-described herein.

Each of the distributed PMICs 14(1)-14(X) includes a distributed voltage amplifier 34 (denoted as “DVA”) coupled in series to a distributed offset capacitor DC_{OFF}. The distributed voltage amplifier 34 is configured to generate a distributed initial voltage DV_{AMP} based on a respective one of the distributed target voltages DV_{TGT-1}-DV_{TGT-X} and a distributed supply voltage DV_{SUP}. The distributed offset capacitor DC_{OFF} can be charged by a respective one of the received low-frequency currents DI_{DC-1}-DI_{DC-X} to raise the distributed initial voltage DV_{AMP} by a distributed offset voltage DV_{OFF} to thereby generate a respective one of the distributed voltages DV_{CC-1}-DV_{CC-X}.

Each of the distributed PMICs 14(1)-14(X) also includes a distributed bypass switch DS_{BYP} having one end coupled in between the distributed voltage amplifier 34 and the distributed offset capacitor DC_{OFF}, and another end to the GND. The distributed bypass switch DS_{BYP} is closed while the distributed offset capacitor DC_{OFF} is being charged toward the distributed offset voltage DV_{OFF} and opened when the distributed offset capacitor DC_{OFF} is charged up to the distributed offset voltage DV_{OFF}. Each of the distributed PMICs 14(1)-14(X) also includes a distributed feedback loop 36 that feeds a copy of a respective one of the distributed voltages DV_{CC-1}-DV_{CC-X} back to the distributed voltage amplifier 34.

Given that the distributed PMICs 14(1)-14(X) are configured to receive the low-frequency currents DI_{DC-1}-DI_{DC-X} from the main PMIC 12, each of the distributed PMICs 14(1)-14(X) does not need the MCP 18 and the power inductor L_{P}. As a result, the distributed PMICs 14(1)-14(X) can each be built with a smaller footprint than the main PMIC 12.

With reference back to FIG. 1, the distributed PMICs 14(1)-14(X) are further coupled to multiple distributed power amplifier circuits 38(1)-38(X) via multiple third conductive paths 40(1)-40(X), respectively. Herein, the distributed PMICs 14(1)-14(X) are configured to provide the distributed voltages DV_{CC-1}-DV_{CC-X} and the received low-frequency currents DI_{DC-1}-DI_{DC-X} to the distributed power amplifier circuits 38(1)-38(X) via the third conductive paths 40(1)-40(X), respectively.

Each of the first conductive paths 30(1)-30(K) is significantly shorter than any of the second conductive paths 32(1)-32(X). As such, each of the main power amplifier circuits 28(1)-28(K) is located closer to the main PMIC 12 than to any of the distributed PMICs 14(1)-14(X). Understandably, each of the first conductive paths 30(1)-30(K) has an inherent trace inductance and each of the main power amplifier circuits 28(1)-28(K) has an inherent capacitance. Each pair of the inherent trace inductance and the inherent capacitance can form an equivalent inductance-capacitance (LC) circuit that can cause a ripple in a respective one of the voltages V_{CC-1}-V_{CC-K} received by a respective one of the main power amplifier circuits 28(1)-28(K). Thus, by shortening the first conductive paths 30(1)-30(K), it is possible to reduce the inherent trace inductance associated with each of the first conductive paths 30(1)-30(K), thus helping to reduce the ripple in each of the voltages V_{CC-1}-V_{CC-K}.

Each of the third conductive paths 40(1)-40(X) is also significantly shorter than any of the second conductive paths 32(1)-32(X). In this regard, each of the distributed power amplifier circuits 38(1)-38(X) is located closer to a respective one of the distributed PMICs 14(1)-14(X) than to the main PMIC 12.

Like the first conductive paths 30(1)-30(K), each of the third conductive paths 40(1)-40(X) also has an inherent trace inductance and each of the distributed power amplifier circuits 38(1)-38(X) also has an inherent capacitance. Each pair of the inherent trace inductance and the inherent capacitance can form an equivalent LC circuit that can cause a ripple in a respective one of the distributed voltages DV_{CC-1}-DV_{CC-X} received by a respective one of the distributed power amplifier circuits 38(1)-38(X). Thus, by shortening the third conductive paths 40(1)-40(X), it is possible to reduce the inherent trace inductance associated with each of the third conductive paths 40(1)-40(X), thus helping to reduce the ripple in each of the distributed voltages DV_{CC-1}-DV_{CC-X}.

As for the second conductive paths 32(1)-32(X) that couple the distributed PMICs 14(1)-14(X) to the main PMIC 12, the distributed PMICs 14(1)-14(X) will not be impacted by the inherent trace inductance associated with each of the second conductive paths 32(1)-32(X), simply because the second conductive paths 32(1)-32(X) are only used to convey the low-frequency currents DI_{DC-1}-DI_{DC-X}.

The main PMIC 12 further includes an input switch circuit 42, an output switch circuit 44, and a control circuit 46. Notably, the input switch circuit 42 and the output switch circuit 44 can each include any number and type of switches, such as a single multi-pole multi-throw (MPMT) switch or multiple single-pole multi-throw (SPMT) switches. The input switch circuit 42 is configured to receive the target voltages V_{TGT-1}-V_{TGT-M} (e.g., from a transceiver circuit). The output switch circuit 44 is configured to couple each of the voltage circuits 16(1)-16(M) to a respective voltage output among the first set of voltage outputs 24(1)-24(K) and the second set of voltage outputs 26(1)-26(X).

The control circuit 46, which can be a field-programmable gate array (FPGA) as an example, can control the input switch circuit 42 to couple any one of the target voltages V_{TGT-1}-V_{TGT-M} to any one of the voltage circuits 16(1)-16(M). Understandably, each of the voltage circuits 16(1)-16(M) is only configured to receive one of the target voltages V_{TGT-1}-V_{TGT-M}. However, it is possible for different ones of the voltage circuits 16(1)-16(M) to receive a same one of the target voltages V_{TGT-1}-V_{TGT-M}.

The control circuit 46 can also control the output switch circuit 44 to couple any one of the voltage circuits 16(1)-16(M) to any one of the first set of voltage outputs 24(1)-24(K) and the second set of voltage outputs 26(1)-26(X). Notably, at any given time, each of the voltage circuits 16(1)-16(M) can only be coupled to one voltage output among the first set of voltage outputs 24(1)-24(K) and the second set of voltage outputs 26(1)-26(X).

When a respective one of the voltage circuits 16(1)-16(M) is coupled to a respective one of the first set of voltage outputs 24(1)-24(K), the control circuit 46 will further control the respective one of the voltage circuits 16(1)-16(M) to provide a respective one of the voltages V_{CC1}-V_{CCM} and a respective one of the low-frequency currents I_{CC1}-I_{CCM} to the respective one of the first set of voltage outputs 24(1)-24(K). In contrast, when a respective one of the voltage circuits 16(1)-16(M) is coupled to a respective one of the second set of voltage outputs 26(1)-26(X), the control circuit 46 will further control the respective one of the voltage circuits 16(1)-16(M) to only provide a respective one of the low-frequency currents I_{CC1}-I_{CCM} to the respective one of the second set of voltage outputs 26(1)-26(X). In a non-limiting example, the control circuit 46 is configured to couple at least two of the voltage circuits 16(1)-16(M) to at least two of the distributed PMICs 14(1)-14(M) via at least two of the second set of voltage outputs 26(1)-26(X), respectively.

The control circuit 46 can further control the input switch circuit 42 to provide a subset of the target voltages V_{TGT-1}-V_{TGT-M} to the distributed PMICs 14(1)-14(X) as the distributed target voltages DV_{TGT-1}-DV_{TGT-X}. According to an embodiment of the present disclosure, the control circuit 46 is configured to provide a respective one of the target voltages V_{TGT-1}-V_{TGT-M} as received by a respective one of the voltage circuits 16(1)-16(M) to a respective one of the distributed PMICs 14(1)-14(X) if the respective one of the distributed PMICs 14(1)-14(X) is coupled to the respective one of the voltage circuits 16(1)-16(M) via a respective one of the second set of voltage outputs 26(1)-26(X). For example, if the control circuit 46 controls the output switch circuit 44 to couple the voltage circuit 16(M) to the distributed PMIC 14(1) via the output switch circuit 44, and controls the input switch circuit 42 to couple the target voltage V_{TGT-1} to the voltage circuit 16(M), the control circuit 46 will then further control the input switch circuit 42 to provide the target voltage V_{TGT-1} to the distributed PMIC 14(1) as the distributed target voltage DV_{TGT-1}.

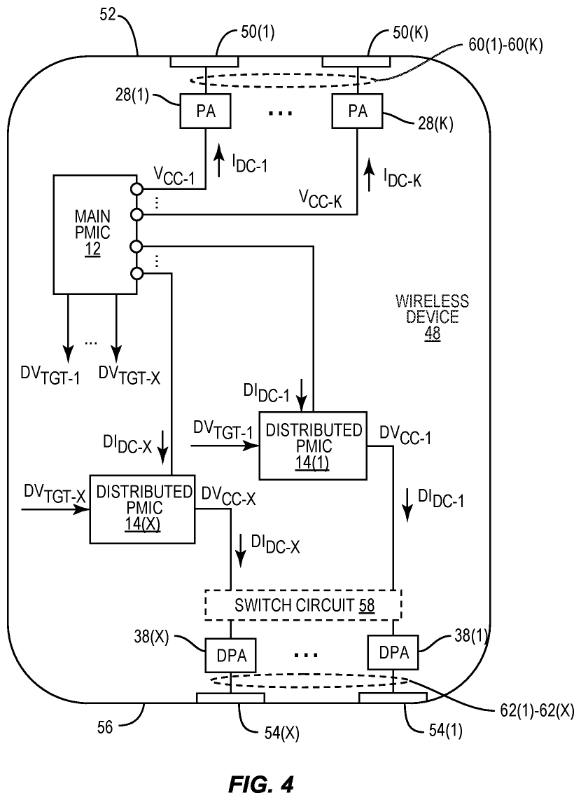

The distributed power management circuit 10 can be provided in a wireless device to enable a flexible antenna configuration. In this regard, FIG. 4 is a schematic diagram of a wireless device 48 incorporating the distributed power management circuit 10 of FIG. 1. Common elements between FIGS. 1 and 4 are shown therein with common element numbers and will not be re-described herein.

The wireless device 48 can include multiple main antennas 50(1)-50(K) disposed on a first side 52 (e.g., upper edge) of the wireless device 48. As such, the main power amplifier circuits 28(1)-28(K) are located closer to the first side 52 and each is coupled to a respective one of the main antennas 50(1)-50(K).

The wireless device 48 also includes multiple distributed antennas 54(1)-54(X) disposed on a second side 56 (e.g., bottom edge) of the wireless device 48. Accordingly, the distributed power amplifier circuits 38(1)-38(X) are located closer to the second side 56 and each is coupled to a respective one of the distributed antennas 54(1)-54(X). In an embodiment, the wireless device 48 may further include a switch circuit 58, which can be controlled to couple any of the distributed PMICs 14(1)-14(X) to any of the distributed power amplifier circuits 38(1)-38(X). Understandably, the switch circuit 58 provides an additional level of configuration flexibility in the wireless device 48.

As shown in FIG. 4, the second side 56 is an opposite side relative to the first side 52. By disposing the main antennas 50(1)-50(K) and the distributed antennas 54(1)-54(X) on the opposite sides, it is possible to mitigate a so-called hand-blocking effect.

The wireless device 48 can be configured to support a variety of transmission scenarios. In one embodiment, the wireless device 48 may be configured to simultaneously transmit via the main antennas 50(1)-50(K) and the distributed antennas 54(1)-54(X). For example, the wireless device 48 can concurrently transmit multiple first radio frequency (RF) signals 60(1)-60(K) from the main antennas 50(1)-50(K) based on multiple-input multiple-output (MIMO) and multiple second RF signals 62(1)-62(X) from the distributed antennas 54(1)-54(X) based on RF beamforming.

In another embodiment, the wireless device 48 may be configured to transmit the second RF signals 62(1)-62(X) via the distributed antennas 54(1)-54(X) only when the main antennas 50(1)-50(K) are blocked, or vice versa. In another embodiment, the wireless device 48 may transmit the first RF signals 60(1)-60(K) based on a first wireless communication technology, such as long-term evolution (LTE) or Wi-Fi and transmit the second RF signals 62(1)-62(X) based on a second wireless communication technology like fifth generation (5G), 5G new radio (5G-NR), or even sixth generation (6G).

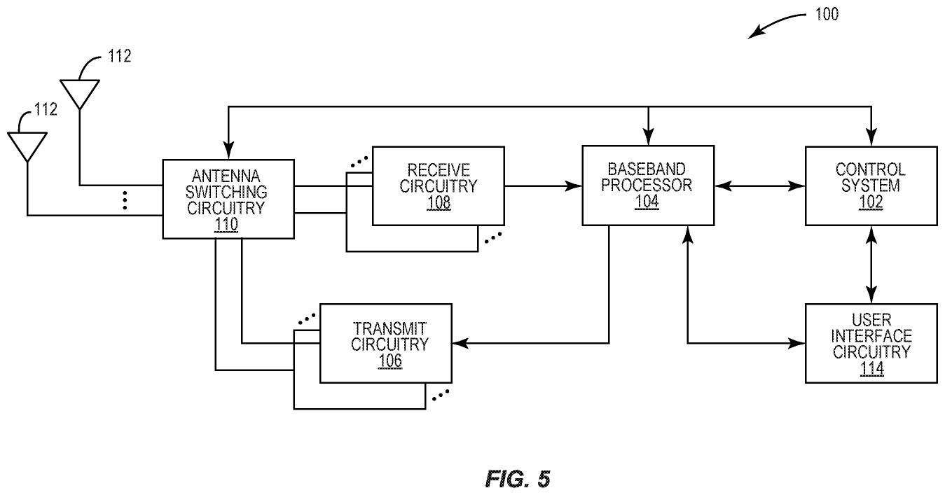

The wireless device 48 of FIG. 4 can be functionally equivalent to a user element. In this regard, FIG. 5 is a schematic diagram of an exemplary user element 100 that can be functionally equivalent to the wireless device 48 of FIG. 4.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

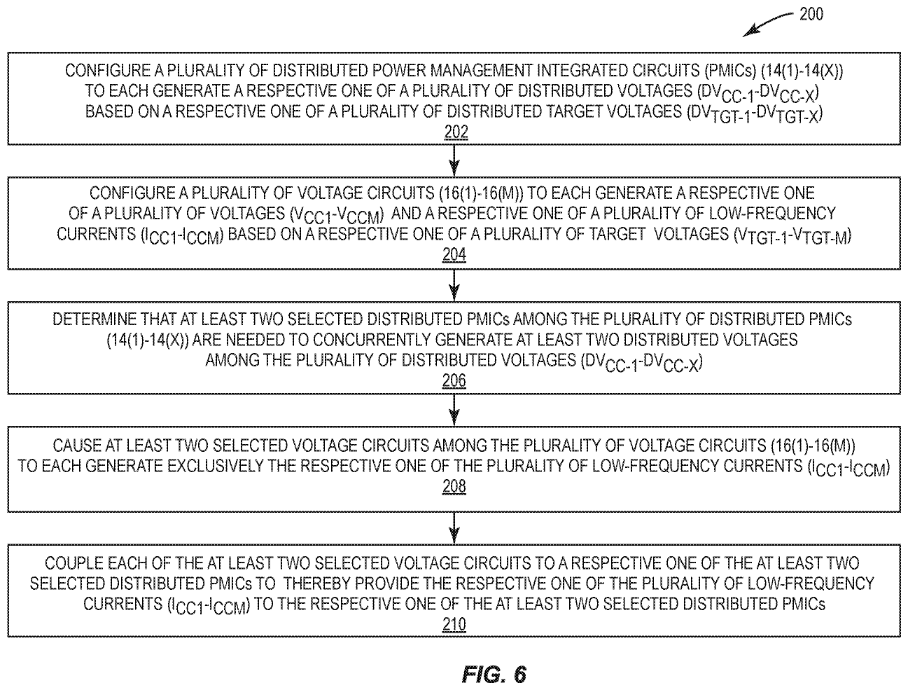

In an embodiment, the distributed power management circuit 10 of FIG. 1 can be configured to operate in the wireless device 48 of FIG. 4 based on a process. In this regard, FIG. 6 is a flowchart of an exemplary process 200 for operating the distributed power management circuit 10 of FIG. 1 in the wireless device 48 of FIG. 4.

Herein, the process 200 includes configuring the distributed PMICs 14(1)-14(X) to each generate a respective one of the distributed voltages DV_{CC-1}-DV_{CC-X} based on a respective one of the distributed target voltages DV_{TGT-1}-DV_{TGT-X} (step 202). The process 200 also includes configuring the voltage circuits 16(1)-16(M) to each generate a respective one of the voltages V_{CC1}-V_{CCM} and a respective one of the low-frequency currents I_{CC1}-I_{CCM} based on a respective one of the target voltages V_{TGT-1}-V_{TGT-M} (step 204). The process 200 also includes determining that at least two selected distributed PMICs among the distributed PMICs 14(1)-14(X) are needed to concurrently generate at least two distributed voltages among the distributed voltages DV_{CC-1}-DV_{CC-X} (step 206). The process 200 also includes causing at least two selected voltage circuits among the voltage circuits 16(1)-16(M) to each generate exclusively the respective one of the low-frequency currents I_{CC1}-I_{CCM} (step 208). The process 200 also includes coupling each of the at least two selected voltage circuits to a respective one of the at least two selected distributed PMICs to thereby provide the respective one of the low-frequency currents I_{CC1}-I_{CCM} to the respective one of the at least two selected distributed PMICs (step 210).

Those skilled in the art will recognize improvements and modifications to the preferred embodiments of the present disclosure. All such improvements and modifications are considered within the scope of the concepts disclosed herein and the claims that follow.

What is claimed is:

1. A distributed power management circuit comprising:
a plurality of distributed power management integrated circuits (PMICs) each configured to generate a respective one of a plurality of distributed voltages based on a respective one of a plurality of distributed target voltages; and
a main PMIC comprising:
a plurality of voltage circuits each configured to generate a respective one of a plurality of voltages and a respective one of a plurality of low-frequency currents based on a respective one of a plurality of target voltages; and
a control circuit configured to:
determine that at least two selected distributed PMICs among the plurality of distributed PMICs are needed to concurrently generate at least two distributed voltages among the plurality of distributed voltages;
cause at least two selected voltage circuits among the plurality of voltage circuits to each generate exclusively the respective one of the plurality of low-frequency currents; and
couple each of the at least two selected voltage circuits to a respective one of the at least two selected distributed PMICs to thereby provide the respective one of the plurality of low-frequency currents to the respective one of the at least two selected distributed PMICs.

2. The distributed power management circuit of claim 1, wherein the main PMIC further comprises:
an input switch circuit coupled to the plurality of distributed PMICs and the plurality of voltage circuits and configured to receive the plurality of target voltages from a transceiver circuit; and
an output switch circuit configured to couple each of the plurality of voltage circuits to any one of a first set of voltage outputs and a second set of voltage outputs, wherein:
each of the first set of voltage outputs is coupled to a respective one of a plurality of main power amplifier circuits; and
each of the second set of voltage outputs is coupled to a respective one of the plurality of distributed PMICs.

3. The distributed power management circuit of claim 2, wherein the control circuit is further configured to control the output switch circuit to couple the at least two selected voltage circuits to at least two of the second set of voltage outputs that are coupled respectively to the at least two selected distributed PMICs.

4. The distributed power management circuit of claim 2, wherein the control circuit is further configured to control the input switch circuit to provide at least two of the plurality of target voltages to the at least two selected distributed PMICs as at least two of the plurality of distributed target voltages.

5. The distributed power management circuit of claim 4, wherein the control circuit is further configured to control the input switch circuit to provide the at least two of the plurality of target voltages to the at least two selected voltage circuits among the plurality of voltage circuits.

6. The distributed power management circuit of claim 2, wherein the control circuit is further configured to:
cause at least one other voltage circuit among the plurality of voltage circuits, which is different from the at least two selected voltage circuits, to generate concurrently the respective one of the plurality of voltages and the respective one of the plurality of low-frequency currents; and
control the output switch circuit to couple the at least one other voltage circuit to at least one of the first set of voltage outputs.

7. The distributed power management circuit of claim 1, wherein each of the plurality of distributed PMICs comprises:
a distributed voltage amplifier configured to generate a respective distributed initial voltage based on the respective one of the plurality of distributed target voltages; and
a distributed offset capacitor configured to raise the respective distributed initial voltage by a respective distributed offset voltage to generate the respective one of the plurality of distributed voltages.

8. The distributed power management circuit of claim 1, wherein the plurality of distributed PMICs is integrated into a single distributed PMIC.

9. The distributed power management circuit of claim 1, wherein the plurality of voltages comprises a mixture of envelope tracking (ET) and average power tracking (APT) voltages.

10. A wireless device comprising:
a distributed power management circuit comprising:
a plurality of distributed power management integrated circuits (PMICs) each configured to generate a respective one of a plurality of distributed voltages based on a respective one of a plurality of distributed target voltages; and
a main PMIC comprising:
a plurality of voltage circuits each configured to generate a respective one of a plurality of voltages and a respective one of a plurality of low-frequency currents based on a respective one of a plurality of target voltages; and
a control circuit configured to:
determine that at least two selected distributed PMICs among the plurality of distributed PMICs are needed to concurrently generate at least two distributed voltages among the plurality of distributed voltages;
cause at least two selected voltage circuits among the plurality of voltage circuits to each generate exclusively the respective one of the plurality of low-frequency currents; and
couple each of the at least two selected voltage circuits to a respective one of the at least two selected distributed PMICs to thereby provide the respective one of the plurality of low-frequency currents to the respective one of the at least two selected distributed PMICs.

11. The wireless device of claim 10, wherein the main PMIC further comprises:
an input switch circuit coupled to the plurality of distributed PMICs and the plurality of voltage circuits and configured to receive the plurality of target voltages from a transceiver circuit; and
an output switch circuit configured to couple each of the plurality of voltage circuits to any one of a first set of voltage outputs and a second set of voltage outputs, wherein:
each of the first set of voltage outputs is coupled to a respective one of a plurality of main power amplifier circuits; and
each of the second set of voltage outputs is coupled to a respective one of the plurality of distributed PMICs.

12. The wireless device of claim 11, further comprising:
a set of main power amplifier circuits each coupled to a respective one of the first set of voltage outputs;
multiple main antennas each coupled to a respective one of the set of main power amplifier circuits;
a set of distributed power amplifier circuits each coupled to a respective one of the plurality of distributed PMICs; and
multiple distributed antennas each coupled to a respective one of the set of distributed power amplifier circuits.

13. The wireless device of claim 12, wherein:
the multiple main antennas are provided on an upper edge of the wireless device; and
the multiple distributed antennas are provided on a bottom edge of the wireless device.

14. The wireless device of claim 12, wherein:
the set of main power amplifier circuits are located closer to the multiple main antennas than to the multiple distributed antennas; and
the set of distributed power amplifier circuits are located closer to the multiple distributed antennas than to the multiple main antennas.

15. The wireless device of claim 12, further configured to simultaneously transmit multiple first radio frequency (RF) signals via the multiple main antennas and multiple second RF signals via the multiple distributed antennas.

16. The wireless device of claim 15, further configured to simultaneously transmit the multiple first RF signals via multiple-input multiple-output (MIMO) and the multiple second RF signals via RF beamforming.

17. The wireless device of claim 15, further configured to simultaneously transmit the multiple first RF signals based on fourth generation (4G) wireless technology and the multiple second RF signals based on fifth generation (5G) wireless technology.

18. The wireless device of claim 12, further configured to simultaneously transmit multiple first radio frequency (RF) signals via the multiple main antennas when the multiple distributed antennas are blocked.

19. The wireless device of claim 12, further configured to simultaneously transmit multiple second radio frequency (RF) signals via the multiple distributed antennas when the multiple main antennas are blocked.

20. A method for operating a distributed power management circuit comprising:
configuring a plurality of distributed power management integrated circuits (PMICs) to each generate a respective one of a plurality of distributed voltages based on a respective one of a plurality of distributed target voltages;
configuring a plurality of voltage circuits to each generate a respective one of a plurality of voltages and a respective one of a plurality of low-frequency currents based on a respective one of a plurality of target voltages;
determining that at least two selected distributed PMICs among the plurality of distributed PMICs are needed to concurrently generate at least two distributed voltages among the plurality of distributed voltages;
causing at least two selected voltage circuits among the plurality of voltage circuits to each generate exclusively the respective one of the plurality of low-frequency currents; and
coupling each of the at least two selected voltage circuits to a respective one of the at least two selected distributed PMICs to thereby provide the respective one of the plurality of low-frequency currents to the respective one of the at least two selected distributed PMICs.
